(19) United States
(12) Patent Application Publication
(10) Pub. No.: US 2024/0217863 A1
(43) Pub. Date: Jul. 4, 2024

(54) OPTICAL GLASS AND ULTRAVIOLET LIGHT EMITTING DEVICE

(71) Applicant: AGC Inc., Tokyo (JP)

(72) Inventors: Daichi SHIRAI, Shizuoka (JP); Makoto SHIRATORI, Shizuoka (JP)

(73) Assignee: AGC Inc., Tokyo (JP)

(21) Appl. No.: 18/391,858

(22) Filed: Dec. 21, 2023

(30) Foreign Application Priority Data
Dec. 28, 2022 (JP) 2022-212585

(51) Int. Cl. C03C 3/068

(52) U.S. Cl. CPC C03C 3/068

(57) ABSTRACT

An optical glass having: a transmittance of light at a wavelength of 270 nm of 50% or more when converted into the transmittance with a thickness of the optical glass being 1.0 mm; an average thermal expansion coefficient in a range of 50° C. to 400° C. of 4.4 ppm/° C. to 7.2 ppm/° C.; a refractive index nd of 1.55 or more; and an Abbe number vd of 50 to 60.

### CROSS-REFERENCE TO RELATED APPLICATIONS

This application is based on and claims priority under 35 USC 119 from Japanese Patent Application No. 2022-212585 filed on Dec. 28, 2022, the entire content of which is incorporated herein by reference.

### TECHNICAL FIELD

The present invention relates to an optical glass and an ultraviolet light emitting device.

### BACKGROUND ART

In recent years, ultraviolet LED elements (light emitting diode elements), which are semiconductor light emitting elements, have been attracting attention as a light source in ultraviolet light emitting devices in place of conventional mercury lamps from the viewpoint of environmental conservation and the like. In particular, deep ultraviolet LED elements having an emission wavelength of about 200 nm to 280 nm can be used, for example, to sterilize viruses and pathogens.

Sapphire or aluminum nitride is used for a substrate of the ultraviolet LED element, and an aluminum nitride substrate can extract light having a low wavelength with higher output than that of a sapphire substrate.

In the ultraviolet LED element, light emitted from a light-emitting layer of the LED element is reflected inside the LED element to cause loss, and thus an efficiency of extracting light to the outside of the LED element is low. In this regard, Patent Literature 1 discloses a technique of providing an inorganic glass on a semiconductor light emitting element via a resin layer.

In a case in which an optical glass is provided on an LED element, it is necessary to use a glass that has an excellent ultraviolet transparency and a refractive index close to that of a substrate from the viewpoint of improving the light extraction efficiency, and has a thermal expansion close to that of the substrate from the viewpoint of a durability of reducing the peeling due to continuous use.

### CITATION LIST

### Patent Literature

Patent Literature 1: JP2022-117119A

### SUMMARY OF INVENTION

However, the thermal expansion and the refractive index are in a trade-off relation, and thus it is technically difficult to achieve both a low thermal expansion and a high refractive index. In addition to that, it is difficult to obtain a glass exhibiting an excellent ultraviolet transparency.

In the technique described in Patent Literature 1, a refractive index of the inorganic glass is 1.74, which is close to that of the sapphire substrate, but a thermal expansion coefficient is not mentioned.

The present invention has been made based on such a background, and an object thereof is to provide an optical glass having an excellent ultraviolet light transmittance, a high refractive index, and a low thermal expansion.

The present invention provides an optical glass having the following configuration and an ultraviolet light emitting device including the optical glass.
(1) An optical glass having:
   a transmittance of light at a wavelength of 270 nm of 50% or more when converted into the transmittance with a thickness of the optical glass being 1.0 mm;
   an average thermal expansion coefficient in a range of 50° C. to 400° C. of 4.4 ppm/° C. to 7.2 ppm/° C.;
   a refractive index nd of 1.55 or more; and
   an Abbe number vd of 50 to 60.
(2) The optical glass according to (1), including, in terms of mol % based on oxides:
   40% to 80% of B₂O₃;
   0% to 25% of SiO₂;
   0% to 30% of Al₂O₃;
   3% to 27% of La₂O₃;
   0% to 10% of ZrO₂;
   73% or more of B₂O₃+SiO₂+Al₂O₃; and
   8% or more of La₂O₃+ZrO₂.
(3) The optical glass according to (1) or (2), being substantially free of Bi₂O₃, TiO₂, WO₃, Nb₂O₃, V₂O₅, CeO₂, Tb₂O₃, MoO₃, In₂O₃, GeO₂, Eu₂O₃, and PbO.
(4) The optical glass according to (1) or (2), being substantially free of an alkali metal oxide.
(5) The optical glass according to (1) or (2), being substantially free of an alkaline earth metal oxide and ZnO.
(6) The optical glass according to (1) or (2), having a content of Fe of 5 ppm by mass or less.
(7) The optical glass according to (1) or (2), having a degradation amount of a spectral transmittance at a wavelength of 450 nm of 3% or less in solarization evaluation.
(8) The optical glass according to (1) or (2), having a glass transition temperature of 600° C. or higher.
(9) An ultraviolet light emitting device including:
   a substrate;
   the optical glass according to (1) or (2) provided on one main surface of the substrate; and
   a light-emitting layer provided on the other main surface of the substrate.

According to the present invention, it is possible to provide the optical glass having an excellent ultraviolet light transmittance, a high refractive index, and a low thermal expansion. In addition, it is possible to provide the ultraviolet light emitting device including the optical glass.

The optical glass of the present invention has the above-described characteristics, and thus can be suitably used in the ultraviolet light emitting device including an aluminum nitride substrate.

### BRIEF DESCRIPTION OF DRAWINGS

FIG. 1 is a graph illustrating a relation between a content of Fe and a transmittance of light having a wavelength of 270 nm in a glass having a thickness of 1.0 mm; and

FIG. 2 is a schematic diagram illustrating a configuration of an ultraviolet light emitting device according to one embodiment of the present invention.

### DESCRIPTION OF EMBODIMENTS

Hereinafter, modes for implementing the present invention will be described in detail. The present invention is not limited to the embodiments to be described below.

In addition, the symbol “—” or the word “to” that is used to express a numerical range includes the numerical values before and after the symbol or the word as the lower limit value and the upper limit value of the range, respectively.

### <Optical Glass>

An optical glass of the present embodiment has a transmittance of light of 50% or more at a wavelength of 270 nm when converted into a thickness of 1.0 mm. When the transmittance of light at the wavelength of 270 nm is 50% or more, an excellent transmittance is exhibited for light having a wavelength in an ultraviolet region, particularly in a deep ultraviolet region. The transmittance of light at the wavelength of 270 nm is preferably 60% or more, more preferably 70% or more, further preferably 75% or more, and particularly preferably 80% or more. In addition, an upper limit of the transmittance of light at the wavelength of 270 nm is not particularly limited, and is, for example, 88% or less.

The transmittance can be measured by an ultraviolet-visible spectrophotometer.

The optical glass of the present embodiment has an average thermal expansion coefficient of 4.4 ppm/° C. to 7.2 ppm/° C. in a range of 50° C. to 400° C. If the average thermal expansion coefficient in the range of 50° C. to 400° C. is within the above-described range, when the optical glass of the present embodiment is used in an ultraviolet light emitting device, the peeling of a bonding surface between the optical glass and an LED element can be reduced, and a durability in continuous use can be improved. In particular, the present invention can be suitably used for the ultraviolet light emitting device including an aluminum nitride substrate. A lower limit value of the average thermal expansion coefficient in the range of 50° C. to 400° C. is preferably 4.6 ppm/° C. or more. In addition, an upper limit value of the average thermal expansion coefficient is preferably 7.0 ppm/° C. or less, more preferably 6.5 ppm/° C. or less, and further preferably 6.3 ppm/° C. or less.

The average thermal expansion coefficient can be measured using a differential thermal dilatometer (for example, Thermo plus EVO2 manufactured by Rigaku).

The optical glass of the present embodiment has a refractive index nd of 1.55 or more. By bringing the refractive index nd of the optical glass close to a refractive index of the substrate of the ultraviolet light emitting device, when the optical glass of the present embodiment is used for the ultraviolet light emitting device, it is possible to reduce the occurrence of loss due to the light emitted from the LED element being reflected inside the LED element.

In the present embodiment, if the refractive index nd of the optical glass is 1.55 or more, for example, even when the optical glass is used in the ultraviolet light emitting device including the aluminum nitride substrate (refractive index: 1.9 to 2.2), the occurrence of the above-described loss can be sufficiently reduced, and a light extraction efficiency is improved. The refractive index nd is more preferably 1.60 or more, and further preferably 1.65 or more. In addition, an upper limit of the refractive index nd is usually 2.00 or less.

The refractive index nd can be measured using a refractometer, and can be measured in detail by using a method described in Examples to be described later.

The optical glass of the present embodiment has an Abbe number vd of 50 to 60. By setting the Abbe number vd to 50 to 60, light can be prevented from being dispersed, and light can be extracted with a uniform output. The Abbe number vd is preferably 51 or more, and more preferably 53 or more. The Abbe number vd is preferably 58 or less, and more preferably 57 or less.

The Abbe number vd can be measured using a refractometer, and can be measured in detail by using a method described in Examples to be described later.

A degradation amount of a spectral transmittance of light at a wavelength of 450 nm of the optical glass of the present embodiment in solarization evaluation is preferably 3% or less. When the degradation amount of the spectral transmittance is 3% or less, a stable light extraction efficiency can also be maintained during long-term use. The degradation amount of the spectral transmittance is more preferably 2% or less, and further preferably 1.5% or less.

In the present specification, “the degradation amount of the spectral transmittance at the wavelength of 450 nm in the solarization evaluation” refers to a degradation amount of a spectral transmittance of light at a wavelength of 450 nm when a glass is irradiated with ultraviolet light. Specifically, an optical glass having a thickness of 1 mm, both surfaces of which are polished, is disposed at a position of 20 cm from a high-pressure mercury lamp of 400 W so as to face each other, and the transmittance before and after irradiation for 120 hours is measured to determine the degradation amount.

The optical glass of the present embodiment preferably has a glass transition temperature of 600° C. or higher. If the glass transition temperature is 600° C. or higher, an LED substrate and a lens can be bonded to each other without causing distortion in the lens during heat bonding. An upper limit of the glass transition temperature is not particularly limited, and is, for example, 800° C. or lower.

A shape of the optical glass of the present embodiment is not particularly limited, and examples thereof include a sheet shape, a lens, a lens array, a diffraction grating, a diffraction optical element, and a grating cell array. In particular, when the optical glass of the present embodiment is used in the ultraviolet light emitting device, the shape of the optical glass is preferably a spherical shape, a hemispherical shape, or an aspherical convex lens shape, and more preferably a hemispherical shape.

### (Compositions of Glass)

Next, one embodiment of a composition range of components that can be contained in the optical glass of the present invention will be described in detail. In a case in which the composition range of the components is expressed as “%” or “ppm”, unless otherwise specified, the composition range means mol % or ppm by mass based on oxides. In addition, “being substantially free of” components means that the components are not contained except for inevitable impurities mixed from raw materials and the like, that is, the components are not intentionally contained.

Examples of composition satisfying the above-described characteristics in the optical glass of the present embodiment contain, in terms of mol % based on oxides:
B₂O₃: 40% to 80%,
SiO₂: 0% to 25%.
Al₂O₃: 0% to 30%.
La₂O₃: 3% to 27%,
ZrO₂: 0% to 10%.
B₂O₃+SiO₂+Al₂O₃: 73% or more, and
La₂O₃+ZrO₂: 8% or more.

B₂O₃ is a component that forms a network structure of a glass. The optical glass of the present embodiment preferably contains 40% to 80% of B₂O₃. If a content of B₂O₃ is 40% or more, the glass is stabilized, and the average thermal expansion coefficient can be prevented from being increased. The content of B₂O₃ is more preferably 45% or more. If the content of B₂O₃ is 80% or less, the glass can be prevented from being devitrified. The content of B₂O₃ is more preferably 75% or less, further preferably 70% or less, particularly preferably 65% or less, and most preferably 60% or less.

SiO₂ is a component that forms a network structure of a glass. Therefore, the optical glass of the present embodiment preferably contains 0% to 25% of SiO₂. When SiO₂ is contained, the glass is stabilized, and the average thermal expansion coefficient can be prevented from being increased. When SiO₂ is contained, a content thereof is preferably 5% or more, more preferably 10% or more, and further preferably 13% or more. In addition, if the content of SiO₂ is 25% or less, the refractive index can be prevented from being decreased, and a dissolution temperature of the glass can be lowered. The content of SiO₂ is more preferably 20% or less, and further preferably 15% or less.

Al₂O₃ is a component that forms a network structure of a glass. Therefore, the optical glass of the present embodiment preferably contains 0% to 30% of Al₂O₃. When Al₂O₃ is contained, the glass is stabilized, and the average thermal expansion coefficient can be prevented from being increased. In addition, a chemical durability of the glass is improved. When Al₂O₃ is contained, a content thereof is preferably 5% or more, more preferably 10% or more, further preferably 15% or more, particularly preferably 20% or more, and most preferably 25% or more. If the content of Al₂O₃ is 30% or less, the glass can be prevented from being devitrified.

La₂O₃ is a component that increases the refractive index and increases the average thermal expansion coefficient of the glass. Therefore, the optical glass of the present embodiment preferably contains 3% to 27% of La₂O₃. If a content of La₂O₃ is 3% or more, the refractive index of the glass can be increased. The content of La₂O₃ is more preferably 5% or more, further preferably 8% or more, and particularly preferably 10% or more. In addition, if the content of La₂O₃ is 27% or less, the average thermal expansion coefficient can be prevented from becoming too large. The content of La₂O₃ is more preferably 24% or less, and further preferably 20% or less.

ZrO₂ is a component that increases the refractive index while reducing the average thermal expansion coefficient of the glass. Therefore, the optical glass of the present embodiment preferably contains 0% to 10% of ZrO₂. When ZrO₂ is contained, a content thereof is preferably 2% or more, and more preferably 5% or more. If the content of ZrO₂ is 10% or less, the glass can be prevented from being devitrified. The content of ZrO₂ is more preferably 8.5% or less, and further preferably 7% or less.

In the optical glass of the present embodiment, a total content of B₂O₃, SiO₂, and Al₂O₃ (B₂O₃+SiO₂+Al₂O₃) is preferably 73% or more. When B₂O₃+SiO₂+Al₂O₃ is 73% or more, the average thermal expansion coefficient can be prevented from becoming too large. B₂O₃+SiO₂+Al₂O₃ is more preferably 75% or more, further preferably 76% or more, particularly preferably 78% or more, and most preferably 80% or more. In addition, from the viewpoint of preventing the glass from being devitrified, B₂O₃+SiO₂+Al₂O₃ is preferably 95% or less, more preferably 92% or less, and particularly preferably 90% or less.

In the optical glass of the present embodiment, a total content of La₂O₃ and ZrO₂ (La₂O₃+ZrO₂) is preferably 8% or more. When La₂O₃+ZrO₂ is 8% or more, the refractive index of the glass can be sufficiently increased. La₂O₃+ZrO₂ is more preferably 10% or more, further preferably 15% or more, and particularly preferably 17% or more. In addition, from the viewpoint of devitrification, La₂O₃+ZrO₂ is preferably 25% or less, and more preferably 20% or less.

The optical glass of the present embodiment preferably contains 0% to 5% of Y₂O₃. Y₂O₃ is a component that increases the average thermal expansion coefficient and increases the refractive index. When Y₂O₃ is contained, a content thereof is more preferably 3% or less.

The optical glass of the present embodiment preferably contains 0% to 10% of Ta₂O₅. Ta₂O₅ is a component that absorbs ultraviolet light and prevents the average thermal expansion coefficient from being increased, and thus can be added within a range not affecting an ultraviolet transparency. When Ta₂O₅ is contained, a content thereof is preferably 5% or less, and more preferably 2.5% or less.

The optical glass of the present embodiment preferably contains 0% to 20% of HfO₂. HfO₂ is a component that absorbs ultraviolet light and increases the refractive index, and thus can be added within a range not affecting the ultraviolet transparency. When HfO₂ is contained, a content thereof is more preferably 7% or less, and further preferably 5% or less.

In the optical glass of the present embodiment, a total content of La₂O₃, ZrO₂, Y₂O₃, Ta₂O₅, and HfO₂ (La₂O₃+ZrO₂+Y₂O₃+Ta₂O₅+HfO₂) is preferably 8% or more. When La₂O₃+ZrO₂+Y₂O₃+Ta₂O₅+HfO₂ is 8% or more, the refractive index of the glass can be sufficiently increased. La₂O₃+ZrO₂+Y₂O₃+Ta₂O₅+HfO₂ is more preferably 10% or more, further preferably 13% or more, and particularly preferably 15% or more. In addition, from the viewpoint of devitrification, La₂O₃+ZrO₂+Y₂O₃+Ta₂O₅+HfO₂ is preferably 25% or less.

The optical glass of the present embodiment may contain 100 ppm or less of Pt. Pt has an effect of decreasing the ultraviolet light transmittance of the glass, but when a content of Pt is 100 ppm or less, the ultraviolet light transmittance can be sufficiently prevented from being decreased. The content of Pt is more preferably 80 ppm or less, further preferably 60 ppm or less, particularly preferably 40 ppm or less, and most preferably 20 ppm or less.

The content of Pt can be analyzed by ICP mass spectrometry.

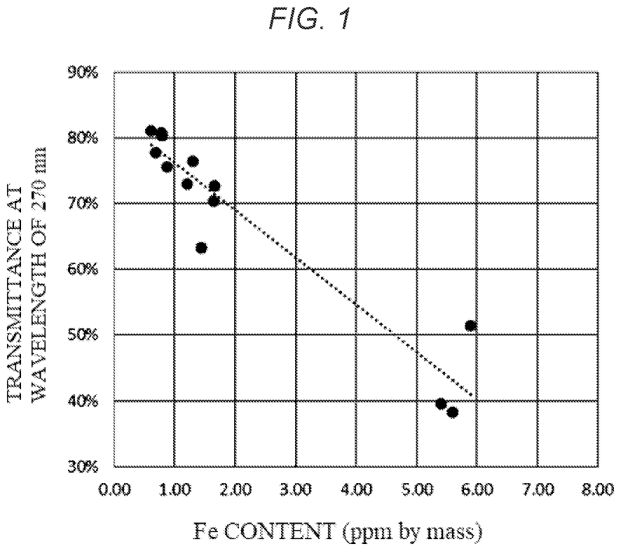

The glass of the present embodiment may contain 5 ppm or less of Fe. Fe has an effect of decreasing the ultraviolet light transmittance of the glass, and as illustrated in FIG. 1, as a content of Fe increases, the transmittance of light at the wavelength of 270 nm when the optical glass is converted into the thickness of 1.0 mm decreases. However, it is difficult to completely avoid the mixing of Fe from a glass raw material and a manufacturing process. In the optical glass of the present embodiment, if the content of Fe is 5 ppm or less, the ultraviolet light transmittance can be sufficiently prevented from being decreased. The content of Fe is more preferably 3 ppm or less, further preferably 2 ppm or less, and particularly preferably 1 ppm or less. An iron component in the glass is present in the glass in a valence of Fe³⁺ or Fe²⁺, but in the present specification, Fe is a total iron content calculated assuming that the iron component contained in the glass is Fe.

The content of Fe can be reduced by using a high-purity raw material as the raw material of the optical glass and managing the raw material with a plastic storage container or a plastic jig.

The content of Fe can be analyzed by the ICP mass spectrometry.

The optical glass of the present embodiment may contain SnO₂ or SnO, or both of them. SnO₂ and SnO act as a reducing agent, and can control an amount of Fe³⁺ that absorbs light in the ultraviolet region, and can improve the ultraviolet light transmittance. A total content of SnO and SnO₂ is preferably 3% or less, more preferably 1% or less, and particularly preferably 0.5% or less in terms of additional when the above-described glass compositions are taken as 100%. The control of the amount of Fe³⁺ can be adjusted by adding the reducing agent (for example, SnO or SnO₂) to the raw material to control a degree of oxidation-reduction of a glass melt, or by dissolving the raw material under a reducing atmosphere (for example, under a nitrogen atmosphere).

The optical glass of the present embodiment may contain, as arbitrary component, components other than those described above (hereinafter, also referred to as “other components”) within a range not exceeding 1%. The other components include those that can be contained by adding a refining agent, and examples thereof include SO₃ and Cl. A total content of the other components is preferably 0.3% or less from the viewpoint of ultraviolet light absorption.

It is preferable that the optical glass of the present embodiment does not contain a component that absorbs light in the ultraviolet region. Specifically, it is preferable that the optical glass of the present embodiment is substantially free of Bi₂O₃, TiO₂, WO₃, Nb₂O₅, V₂O₅, CeO₂, Tb₂O₃, MoO₃, In₂O₃, GeO₂, Eu₂O₃, and PbO. In the present embodiment, being substantially free of the above-described components means that, for example, a total content of the above-described components is 0.1% or less.

It is preferable that the optical glass of the present embodiment is substantially free of alkali metal oxides. Here, the alkali metal oxides mean five of Li₂O, Na₂O, K₂O, Rb₂O, and Cs₂O. The optical glass of the present embodiment is substantially free of the alkali metal oxides, and thus the average thermal expansion coefficient can be prevented from being increased. In the present embodiment, being substantially free of alkali metal oxides means that, for example, a total content of the alkali metal oxides (a total content of Li₂O, Na₂O, K₂O, Rb₂O, and Cs₂O) is 0.1% or less.

It is preferable that the optical glass of the present embodiment is substantially free of alkaline earth metal oxides and ZnO. Here, the alkaline earth metal oxides mean four of MgO, CaO, SrO, and BaO. The optical glass of the present embodiment is substantially free of the alkaline earth metal oxides and ZnO, and thus the average thermal expansion coefficient can be prevented from being increased. In the present embodiment, being substantially free of alkaline earth metal oxides and ZnO means that, for example, a total content of the alkaline earth metal oxides and ZnO (a total content of MgO, CaO, SrO, BaO, and ZnO) is 0.1% or less.

<Method for manufacturing Optical Glass>

The optical glass of the present embodiment can be manufactured by using, for example, a melt quenching method. The melt quenching method is a method in which a raw material is heated to be in a molten state and then quenched to obtain an amorphous glass. Specifically, for example, the method for manufacturing an optical glass includes the following steps. First, raw materials are weighed and mixed so as to fall within the above-described composition range (mixing step). The raw material mixture is placed in a platinum crucible and heated at a temperature of 1300° C. to 1400° C. in an electric furnace to dissolve the raw materials (dissolution step). After sufficiently stirring and refining the raw material mixture, the mixture is cast into a mold and molded into a predetermined shape (molding step).

In the dissolution step, the raw materials are preferably heated at 1400° C. or lower. If the heating temperature is 1400° C. or lower, platinum can be prevented from being eluted from the platinum crucible. From the viewpoint of homogenization, the heating temperature is preferably 1200° C. or higher. In addition, a heating time is not particularly limited, and is preferably within a range of, for example, 1 hour to 120 hours from the viewpoint of preventing platinum from being eluted.

Examples of a method for heating raw materials include a method using an electric furnace.

When Fe is contained in the optical glass, Fe is present as Fe²⁺ or Fe³⁺ in the glass. Fe²⁺ absorbs light having a wavelength of 800 nm to 1400 nm, and Fe³⁺ absorbs light having a wavelength of 200 nm to 300 nm. Therefore, from the viewpoint of improving the ultraviolet light transmittance, Fe is preferably present in the state of Fe²⁺ in the glass. Therefore, the dissolution step is preferably performed under a reducing atmosphere. Specific examples of the reducing atmosphere include a nitrogen atmosphere.

### Application

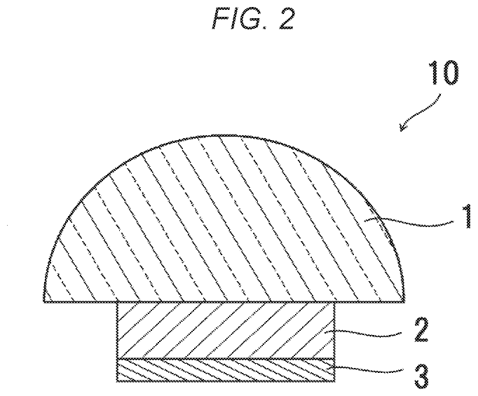

The optical glass of the present embodiment is preferably used in the ultraviolet light emitting device including a light-emitting layer. For example, as illustrated in FIG. 2, a configuration of an ultraviolet light emitting device 10 includes a substrate 2, an optical glass 1 of the present embodiment provided on one main surface of the substrate 2, and a light-emitting layer 3 provided on the other main surface of the substrate 2.

Examples of the light-emitting layer include an ultraviolet LED element of a semiconductor light emitting element having a peak wavelength in a wavelength range of 250 nm to 400 nm.

Examples of the substrate include an aluminum nitride substrate and a sapphire substrate. Among the substrates, the aluminum nitride substrate is preferable because the aluminum nitride substrate allows light having a low wavelength to be extracted with a high output.

An average thermal expansion coefficient of the substrate is, for example, 4.5 ppm/° C. to 7.0 ppm/° C. In addition, a refractive index nd of the substrate is, for example, 1.76 to 2.2. The optical glass of the present embodiment is bonded to the main surface of the substrate on which the light-emitting layer is not provided.

When the optical glass of the present embodiment is bonded to the substrate, the optical glass of the present embodiment preferably has a hemispherical lens shape or the like. With the hemispherical lens shape, light emitted from the light-emitting element passes through the optical glass and is emitted to the outside of the ultraviolet light emitting device. The optical glass of the present embodiment has an excellent ultraviolet light transmittance and a large refractive index, and thus the loss of the light emitted from the light-emitting layer is reduced, and the light extraction efficiency is improved. Further, the optical glass has a thermal expansion coefficient close to that of the aluminum nitride substrate, and thus it is possible to prevent the peeling of the lens in continuous use.

The ultraviolet light emitting device may include a contact layer, a second substrate, and the like in addition to the optical glass, the substrate (referred to as a first substrate), and the light-emitting layer described above. For example, the ultraviolet light emitting device is formed by laminating the second substrate, the contact layer, the light-emitting layer, the first substrate, and the optical glass of the present embodiment in this order.

As described above, the following configurations are disclosed in the present specification.
(1) An optical glass having:
   a transmittance of light at a wavelength of 270 nm of 50% or more when converted into the transmittance with a thickness of the optical glass being 1.0 mm;
   an average thermal expansion coefficient in a range of 50° C. to 400° C. of 4.4 ppm/° C. to 7.2 ppm/° C.;
   a refractive index nd of 1.55 or more; and
   an Abbe number vd of 50 to 60.
(2) The optical glass according to (1), including, in terms of mol % based on oxides:
   40% to 80% of B₂O₃;
   0% to 25% of SiO₂;
   0% to 30% of Al₂O₃;
   3% to 27% of La₂O₃;
   0% to 10% of ZrO₂;
   73% or more of B₂O₃+SiO₂+Al₂O₃; and
   8% or more of La₂O₃+ZrO₂.
(3) The optical glass according to (1) or (2), being substantially free of Bi₂O₃, TiO₂, WO₃, Nb₂O₅, V₂O₅, CeO₂, Tb₂O₃, MoO₃, In₂O₃, GeO₂, Eu₂O₃, and PbO.
(4) The optical glass according to any one of (1) to (3), being substantially free of an alkali metal oxide.
(5) The optical glass according to any one of (1) to (4), being substantially free of an alkaline earth metal oxide and ZnO.
(6) The optical glass according to any one of (1) to (5), having a content of Fe of 5 ppm by mass or less.
(7) The optical glass according to any one of (1) to (6), having a degradation amount of a spectral transmittance at a wavelength of 450 nm of 3% or less in solarization evaluation.
(8) The optical glass according to any one of (1) to (7), having a glass transition temperature of 600° C. or higher.
(9) An ultraviolet light emitting device including:
   a substrate;
   the optical glass according to any one of (1) to (8) provided on one main surface of the substrate; and
   a light-emitting layer provided on the other main surface of the substrate.

### EXAMPLES

Examples will be described below, and the present invention is not limited to these examples.

In the following examples, Examples 1 to 23 are working examples, and Examples 24 to 28 are comparative examples.

### [Production of Optical Glass]

The raw materials were weighed so as to have chemical compositions (mol % based on oxides) shown in Tables 1 and 2. As the raw materials, high-purity raw materials used for an ordinary optical glass, such as oxides, hydroxides, carbonates, nitrates, fluorides, hydroxides, and metaphosphoric acid compounds corresponding to the raw materials of each components, were selected and used.

A value of SnO₂ in the table is an amount (mol %) of SnO₂ contained additionally with respect to 100 mol % in total of the components excluding SnO₂.

The weighed raw materials were uniformly mixed, placed in a platinum crucible having an inner volume of about 300 mL, melted, refined, and stirred at about 1400° C. for about 2 hours in an electric furnace, cast into a rectangular mold having a length of 50 mm and a width of 100 mm, and then slowly cooled at about 1° C./min to obtain a sample having a thickness of 30 mm.

An atmosphere (dissolution atmosphere) in the electric furnace was set to an air atmosphere or a nitrogen (N₂) atmosphere as shown in Table 1.

Each sample obtained above was evaluated as follows, and results are shown in Tables 1 and 2 below. Blank columns in the table indicate that the value was not measured. In addition, [—] in the table indicates that the glass was not measured because the glass was devitrified.

### <Transmittance>

A transmittance of light at a wavelength of 300 nm to 2500 nm was measured using a spectrophotometer (V-570, manufactured by JASCO Corporation), and the transmittance was converted into a value of a thickness of 1.0 mm. The transmittance of light at the wavelength of 270 nm was determined from the converted transmittance.

### <Average Thermal Expansion Coefficient (CTE)>

The glass was processed into a rectangular column shape having a side of 5 mm and a height of 20 mm, and a thermal expansion coefficient in a range of 50° C. to 400° C. was measured at a temperature rising rate of 10° C./min using the differential thermal dilatometer (Thermo plus EVO2 manufactured by Rigaku).

### <Glass Transition Temperature (Tg)>

The glass was processed into a rectangular column shape having a side of 5 mm and a height of 20 mm, and a glass transition temperature (Tg) was a value (° C.) measured at the temperature rising rate of 10° C./min using the differential thermal dilatometer (Thermo plus EVO2 manufactured by Rigaku).

<Refractive Index (nd)>

The glass was processed into a rectangular prism having a side of 30 mm and a thickness of 10 mm, and a refractive index (nd) was measured by a refractometer (device name: KPR-2000, manufactured by Kalnew).

<Abbe Number (vd)>

An Abbe Number (vd) was calculated using the sample used for measuring the above-described refractive index based on vd=(nd−1)/(nF−nC). nd is a refractive index for a helium d line, nF is a refractive index for a hydrogen F line, and nC is a refractive index for a hydrogen C line. These refractive indexes were also measured using the above-described refractometer.

### <Solarization Evaluation>

A glass sheet having a thickness of 1 mm, both surfaces of which are polished, was disposed at a position of 20 cm from a high-pressure mercury lamp of 400 W so as to face each other, and a degradation amount in a spectral transmittance was measured when the transmittances before and after irradiation for 120 hours were measured.

TABLE 1

| | | Example 1 | Example 2 | Example 3 | Example 4 | Example 5 | Example 6 | Example 7 |
|---|---|---|---|---|---|---|---|---|
| Compositions | B₂O₃ | 75.0 | 60.0 | 65.0 | 56.0 | 65.0 | 60.0 | 60.0 |
| [mol %] | SiO₂ | 0.0 | 0.0 | 5.0 | 20.0 | 10.0 | 0.0 | 0.0 |
| | Al₂O₃ | 10.0 | 25.0 | 15.0 | 0.0 | 10.0 | 25.0 | 25.0 |
| | La₂O₃ | 15.0 | 15.0 | 15.0 | 24.0 | 15.0 | 10.0 | 10.0 |
| | ZrO₂ | 0.0 | 0.0 | 0.0 | 0.0 | 0.0 | 5.0 | 0.0 |
| | Y₂O₃ | 0.0 | 0.0 | 0.0 | 0.0 | 0.0 | 0.0 | 5.0 |
| | Ta₂O₅ | 0.0 | 0.0 | 0.0 | 0.0 | 0.0 | 0.0 | 0.0 |
| | HfO₂ | 0.0 | 0.0 | 0.0 | 0.0 | 0.0 | 0.0 | 0.0 |
| | Na₂O | 0.0 | 0.0 | 0.0 | 0.0 | 0.0 | 0.0 | 0.0 |
| | SnO₂ | 0.3 | 0.3 | 0.3 | 0.3 | 0.3 | 0.3 | 0.3 |
| | (additional) | | | | | | | |
| | Total | 100.3 | 100.3 | 100.3 | 100.3 | 100.3 | 100.3 | 100.3 |
| | B₂O₃ + Al₂O₃ + | 85.0 | 85.0 | 85.0 | 76.0 | 85.0 | 85.0 | 85.0 |
| | SiO₂ | | | | | | | |
| | La₂O₃ + ZrO₂ | 15.0 | 15.0 | 15.0 | 24.0 | 15.0 | 15.0 | 10.0 |
| | (La₂O₃ + Y₂O₃ + | 15.0 | 15.0 | 15.0 | 24.0 | 15.0 | 15.0 | 15.0 |
| | ZrO₂ + | | | | | | | |
| | Ta₂O₅ + HfO₂) | | | | | | | |
| Evaluation of | Transmittance | 62.9 | 50.2 | 67.1 | 75.9 | 70.3 | 61.9 | 70.0 |
| Physical | (270 nm) [%] | | | | | | | |
| Properties | CTE (50° C. | 5.75 | 5.13 | 5.68 | 7.2 | 5.47 | 5.3 | 5.59 |
| | to 400° C.) | | | | | | | |
| | [ppm/° C.] | | | | | | | |
| | Tg [° C.] | 675 | 682 | 675 | 687 | 673 | 698 | 697 |
| | Tx [° C.] | 712 | 723 | 717 | 723 | 715 | 738 | 742 |
| | nd | 1.65 | 1.66 | 1.66 | 1.74 | 1.66 | 1.65 | 1.66 |
| | vd | 55 | 56 | 55 | 51 | 54 | 55 | 56 |
| Solarization Evaluation [%] | | | | | | | | |
| Dissolution Atmosphere | | Atmosphere | Atmosphere | Atmosphere | Atmosphere | Atmosphere | Atmosphere | Atmosphere |
| | | Example 8 | Example 9 | Example 10 | Example 11 | Example 12 | Example 13 | Example 14 |
| Compositions | B₂O₃ | 55.0 | 50.0 | 50.0 | 45.0 | 60.0 | 65.0 | 55.0 |
| [mol %] | SiO₂ | 10.0 | 0.0 | 15.0 | 20.0 | 0.0 | 0.0 | 10.0 |
| | Al₂O₃ | 25.0 | 30.0 | 25.0 | 25.0 | 27.0 | 27.0 | 25.0 |
| | La₂O₃ | 10.0 | 20.0 | 10.0 | 10.0 | 13.0 | 8.0 | 8.0 |
| | ZrO₂ | 0.0 | 0.0 | 0.0 | 0.0 | 0.0 | 0.0 | 2.0 |
| | Y₂O₃ | 0.0 | 0.0 | 0.0 | 0.0 | 0.0 | 0.0 | 0.0 |
| | Ta₂O₅ | 0.0 | 0.0 | 0.0 | 0.0 | 0.0 | 0.0 | 0.0 |
| | HfO₂ | 0.0 | 0.0 | 0.0 | 0.0 | 0.0 | 0.0 | 0.0 |
| | Na₂O | 0.0 | 0.0 | 0.0 | 0.0 | 0.0 | 0.0 | 0.0 |
| | SnO₂ | 0.3 | 0.3 | 0.3 | 0.3 | 0.3 | 0.3 | 0.3 |
| | (additional) | | | | | | | |
| | Total | 100.3 | 100.3 | 100.3 | 100.3 | 100.3 | 100.3 | 100.3 |
| | B₂O₃ + Al₂O₃ + | 90.0 | 80.0 | 90.0 | 90.0 | 87.0 | 92.0 | 90.0 |
| | SiO₂ | | | | | | | |
| | La₂O₃ + ZrO₂ | 10.0 | 20.0 | 10.0 | 10.0 | 13.0 | 8.0 | 10.0 |
| | (La₂O₃ + Y₂O₃ + | 10.0 | 20.0 | 10.0 | 10.0 | 13.0 | 8.0 | 10.0 |
| | ZrO₂ + | | | | | | | |
| | Ta₂O₅ + HfO₂) | | | | | | | |
| Evaluation of | Transmittance | 66.1 | 76.2 | 66.4 | 68.1 | 67.8 | 61.7 | 60.8 |
| Physical | (270 nm) [%] | | | | | | | |
| Properties | CTE (50° C. | 4.89 | 6.29 | 4.92 | 4.62 | 5.3 | 5.09 | 5.12 |
| | to 400° C.) | | | | | | | |
| | [ppm/° C.] | | | | | | | |
| | Tg [° C.] | 686 | 685 | 692 | 696 | 690 | 686 | 687 |
| | Tx [° C.] | 734 | 729 | 743 | 750 | 734 | 731 | 735 |
| | nd | 1.62 | 1.74 | 1.63 | 1.63 | 1.65 | 1.60 | 1.62 |
| | vd | 57 | 56 | 57 | 56 | 57 | 59 | 57 |

| | | | | | | | |
|---|---|---|---|---|---|---|---|
| Solarization Evaluation [%] | 0 | 0 | | | | | |
| Dissolution Atmosphere | Atmosphere | Atmosphere | Atmosphere | Atmosphere | Atmosphere | Atmosphere | Atmosphere |

TABLE 2

| | | Example 15 | Example 16 | Example 17 | Example 18 | Example 19 | Example 20 | Example 21 |
|---|---|---|---|---|---|---|---|---|
| Compositions | B₂O₃ | 45.0 | 52.5 | 45.0 | 55.0 | 55.0 | 45.0 | 55.0 |
| [mol %] | SiO₂ | 10.0 | 10.0 | 13.0 | 10.0 | 10.0 | 13.0 | 0.0 |
| | Al₂O₃ | 25.0 | 25.0 | 25.0 | 20.0 | 20.0 | 25.0 | 25.0 |
| | La₂O₃ | 10.0 | 10.0 | 10.0 | 10.0 | 10.0 | 10.0 | 10.0 |
| | ZrO₂ | 10.0 | 0.0 | 7.0 | 0.0 | 0.0 | 0.0 | 0.0 |
| | Y₂O₃ | 0.0 | 0.0 | 0.0 | 0.0 | 0.0 | 0.0 | 0.0 |
| | Ta₂O₅ | 0.0 | 2.5 | 0.0 | 5.0 | 0.0 | 0.0 | 0.0 |
| | HfO₂ | 0.0 | 0.0 | 0.0 | 0.0 | 5.0 | 7.0 | 10.0 |
| | Na₂O | 0.0 | 0.0 | 0.0 | 0.0 | 0.0 | 0.0 | 0.0 |
| | SnO₂ | 0.3 | 0.3 | 0.3 | 0.3 | 0.0 | 0.0 | 0.0 |
| | (additional) | | | | | | | |
| | Total | 100.3 | 100.3 | 100.3 | 100.3 | 100.0 | 100.0 | 100.0 |
| | B₂O₃ + Al₂O₃ + | 80.0 | 87.5 | 83.0 | 85.0 | 85.0 | 83.0 | 80.0 |
| | SiO₂ | | | | | | | |
| | La₂O₃ + ZrO₂ | 20.0 | 10.0 | 17.0 | 10.0 | 10.0 | 10.0 | 10.0 |
| | (La₂O₃ + Y₂O₃ + | 20.0 | 12.5 | 17.0 | 15.0 | 15.0 | 17.0 | 20.0 |
| | ZrO₂ + | | | | | | | |
| | Ta₂O₅ + HfO₂) | | | | | | | |
| Evaluation of | Transmittance | 63.4 | 63.7 | 70.6 | 53.4 | 84.1 | 76.0 | 73.8 |
| Physical | (270 nm) [%] | | | | | | | |
| Properties | CTE (50° C. | 5.28 | 4.4 | 4.73 | 5.11 | 5.17 | 4.95 | 5.17 |
| | to 400° C.) | | | | | | | |
| | [ppm/° C.] | | | | | | | |
| | Tg [° C.] | 711 | 691 | 707 | 679 | 681 | 701 | 697 |
| | Tx [° C.] | 761 | 738 | 754 | 722 | 725 | 747 | 740 |
| | nd | 1.67 | 1.63 | 1.66 | 1.64 | 1.63 | 1.64 | 1.64 |
| | vd | 53 | 56 | 54 | 54 | 56 | 57 | 57 |
| Solarization Evaluation [%] | | | | 0 | | 0.1 | | 1.3 |
| Dissolution Atmosphere | | Atmosphere | Atmosphere | Atmosphere | Atmosphere | Atmosphere | Atmosphere | Atmosphere |
| | | Example 22 | Example 23 | Example 24 | Example 25 | Example 26 | Example 27 | Example 28 |
| Compositions | B₂O₃ | 45.0 | 55.0 | 63.0 | 45.0 | 55.0 | 65.0 | 14.0 |
| [mol %] | SiO₂ | 10.0 | 10.0 | 10.0 | 20.0 | 10.0 | 5.0 | 75.0 |
| | Al₂O₃ | 20.0 | 25.0 | 0.0 | 15.0 | 15.0 | 0.0 | 3.0 |
| | La₂O₃ | 20.0 | 10.0 | 27.0 | 10.0 | 10.0 | 25.0 | 4.0 |
| | ZrO₂ | 0.0 | 0.0 | 0.0 | 10.0 | 0.0 | 0.0 | 0.0 |
| | Y₂O₃ | 0.0 | 0.0 | 0.0 | 0.0 | 0.0 | 5.0 | 0.0 |
| | Ta₂O₅ | 5.0 | 0.0 | 0.0 | 0.0 | 10.0 | 0.0 | 0.0 |
| | HfO₂ | 0.0 | 0.0 | 0.0 | 0.0 | 0.0 | 0.0 | 0.0 |
| | Na₂O | 0.0 | 0.0 | 0.0 | 0.0 | 0.0 | 0.0 | 4.0 |
| | SnO₂ | 0.0 | 0.0 | 0.3 | 0.3 | 0.3 | 0.3 | 0.3 |
| | (additional) | | | | | | | |
| | Total | 100.0 | 100.3 | 100.3 | 100.3 | 100.3 | 100.3 | 100.3 |
| | B₂O₃ + Al₂O₃ + | 75.0 | 90.0 | 73.0 | 80.0 | 80.0 | 70.0 | 92.0 |
| | SiO₂ | | | | | | | |
| | La₂O₃ + ZrO₂ | 20.0 | 10.0 | 27.0 | 20.0 | 10.0 | 25.0 | 4.0 |
| | (La₂O₃ + Y₂O₃ + | 25.0 | 10.0 | 27.0 | 20.0 | 20.0 | 30.0 | 4.0 |
| | ZrO₂ + | | | | | | | |
| | Ta₂O₅ + HfO₂) | | | | | | | |
| Evaluation of | Transmittance | 64.5 | 87.7 | — | — | 31.3 | 75.3 | 82.1 |
| Physical | (270 nm) [%] | | | | | | | |
| Properties | CTE (50° C. | 6.46 | 4.89 | — | — | 4.90 | 7.4 | 3.9 |
| | to 400° C.) | | | | | | | |
| | [ppm/° C.] | | | | | | | |
| | Tg [° C.] | 684 | 686 | — | — | 668 | 692 | 598 |
| | Tx [° C.] | 729 | 734 | — | — | 714 | 738 | 648 |
| | nd | 1.74 | 1.62 | — | — | 1.66 | 1.77 | 1.52 |
| | vd | 53 | 57 | — | — | 57 | 49 | 62 |

| | | | | | | | |
|---|---|---|---|---|---|---|---|
| Solarization Evaluation [%] | | 0 | | | | | |
| Dissolution Atmosphere | Atmosphere | N₂ | Atmosphere | Atmosphere | Atmosphere | Atmosphere | Atmosphere |

It was found that the optical glasses in Examples 1 to 23, which are working examples, each have an excellent ultraviolet light transmittance, a low thermal expansion, and a high refractive index as compared with Examples 24 to 28, which are comparative examples.

On the other hand, the optical glasses in Examples 24 and 25, which are comparative examples, were devitrified, and thus the measurement cannot be performed. Further, Example 26, which is a comparative example, had a transmittance of light at a wavelength of 270 nm of less than 50%. Further, Example 27, which is a comparative example, had an average thermal expansion coefficient of more than 7.2 ppm/° C. and an Abbe number of less than 50. In addition, Example 27, which is a comparative example, had an average thermal expansion coefficient of less than 4.4 ppm/° C., a refractive index of less than 1.55, and an Abbe number of more than 60.

The present invention has been described in detail with reference to specific embodiments, but it will be apparent to those skilled in the art that various changes and modifications can be made without departing from the spirit and scope of the present invention.

What is claimed is:

1. An optical glass having:
a transmittance of light at a wavelength of 270 nm of 50% or more when converted into the transmittance with a thickness of the optical glass being 1.0 mm;
an average thermal expansion coefficient in a range of 50° C. to 400° C. of 4.4 ppm/° C. to 7.2 ppm/° C.;
a refractive index nd of 1.55 or more; and
an Abbe number vd of 50 to 60.

2. The optical glass according to claim 1, comprising, in terms of mol % based on oxides:
40% to 80% of B₂O₃;
0% to 25% of SiO₂;
0% to 30% of Al₂O₃;
3% to 27% of La₂O₃;
0% to 10% of ZrO₂;
73% or more of B₂O₃+SiO₂+Al₂O₃; and
8% or more of La₂O₃+ZrO₂.

3. The optical glass according to claim 1, being substantially free of Bi₂O₃, TiO₂, WO₃, Nb₂O₅, V₂O₅, CeO₂, Tb₂O₃, MoO₃, In₂O₃, GeO₂, Eu₂O₃, and PbO.

4. The optical glass according to claim 1, being substantially free of an alkali metal oxide.

5. The optical glass according to claim 1, being substantially free of an alkaline earth metal oxide and ZnO.

6. The optical glass according to claim 1, having a content of Fe of 5 ppm by mass or less.

7. The optical glass according to claim 1, having a degradation amount of a spectral transmittance at a wavelength of 450 nm of 3% or less in solarization evaluation.

8. The optical glass according to claim 1, having a glass transition temperature of 600° C. or higher.

9. An ultraviolet light emitting device comprising:
a substrate,
the optical glass according to claim 1 provided on one main surface of the substrate; and
a light-emitting layer provided on the other main surface of the substrate.
